(19) United States
(12) Patent Application Publication
(10) Pub. No.: US 2004/0152240 A1
(43) Pub. Date: Aug. 5, 2004

(54) Method and apparatus for the use of self-assembled nanowires for the removal of heat from integrated circuits

(76) Inventor: Carlos Dangelo, Los Gatos, CA (US)

Correspondence Address: D'Arcy H. Lorimer, 230 Houston Way, Pismo Beach, CA, 93449, US

(21) Appl. No.: 10/762,666

(22) Filed: Jan. 22, 2004

Related U.S. Application Data
(60) Provisional application No. 60/442,450, filed on Jan. 24, 2003.

(51) Int. Cl. H01L 21/44; H01L 21/48

(52) U.S. Cl. 438/122; 257/706

(57) ABSTRACT

This invention relates to the conduction of heat within the structure of an integrated circuit. The invention discloses a heat conduction device and a method of fabricating same, that utilizes thermally conductive vias to extract heat from local power generating regions of the substrate to top or bottom surfaces of the integrated circuit die. Conductive vias contain self-assembled carbon nanotubes for the enhancement of heat conduction out of the integrated circuit.

### REFERENCES TO PRIOR APPLICATIONS

This application is related to co-pending provisional application No. 60/442,450 filed Jan. 24, 2003 entitled METHOD AND APPARATUS FOR THE USE OF SELF-ASSEMBLED NANOWIRES IN THE DESIGN AND FABRICATION OF INTEGRATED CIRCUITS, and claims benefit thereof.

### BACKGROUND OF THE INVENTION

1. Field of the Invention

This invention relates to the conduction of heat and electrical signals within the structure of an integrated circuit. More specifically, this invention discloses the application of self-assembled nano-wires for the enhancement of heat conduction out of the integrated circuit, and the for increasing the speed of electrical signals propagated within the integrated circuit.

2. Description of the Related Art

Prior art used to cool semiconductor ICs incorporates the use of large and expensive chip packaging having externally mounted, finned heat sinks coupled to the ceramic or plastic encapsulated IC chip. As the speed and density of modern integrated circuits increase, the power generated by these chips also increases, often in geometric proportion to increasing density and functionality. In the video processing and CPU application areas, the ability to dissipate the heat being generated by current ICs is becoming a serious limitation in the advance of technology. While some aspects of the problem can be mitigated by forced convection devices such as fans (and even liquid cooling), the core of the problem is now shifting to the thermal resistances within the chip itself. Reducing the outer package surface temperature is producing diminishing returns due to the high heat fluxes being generated at the semiconductor junctions, and the relatively poor thermal conductivity of the materials between the junction and the outer package surface. This problem is producing high junction temperatures which directly affect chip reliabilities. Other than the available chip design techniques used to minimize chip's power generation (lowering voltage, clocking schemes to turn-off transistors when inactive, decrease the size of specific, non-critical transistors, etc.), the current art does not provide any particular structure inside the chip to carry heat out and reduce junction temperatures.

Heat generated near or at the silicon active devices (semiconductor junctions) is dissipated through two paths:

a) through the inter-metal dielectrics and metal layers to the top bonding layer, or

b) through the bulk silicon towards the bottom of the wafer where thermal contact is made to the back of the chip with the package's heat sink.

Both paths have high thermal resistance. In the current art, the limiting factors are the ‘insulator’ thermal characteristics of dielectrics and bulk silicon materials. More limiting yet is the fact that the path to heat conduction is usually at the bottom or back of the chip through the bulky silicon substrate. As the number of metal and insulator layers grows to accommodate chip interconnect an increase of their temperature is anticipated. With heat sinking only at one side of the chip it becomes harder to ‘cool’ the chip. As a result, large and fast-switching transistors can have their individual junction temperature rise above certain maximum values. This is also true for metal wires with high current and switching activity.

What is needed is a structure in close proximity to the power generating semiconductor junctions specifically designed to conduct heat to the chip outer surfaces. Such a structure should be compatible with current semiconductor fabrication technology, provide significantly lower thermal resistances, and be low cost.

Aside from thermal considerations, a related problem concerns the art used to electrically interconnect the large number of devices inside silicon/CMOS ICs. The current art uses multiple metal layers, insulated by dielectrics, and connected layer to layer by vias. Interconnect conductors are made of metals such as tungsten, aluminum and/or copper. Insulating dielectrics are made from a wide variety of materials, and may be organic or inorganically based. Interconnect conductors are used to provide both signal and power connections to various semiconductor devices within the CMOS chip.

Because of ever decreasing dimensions of horizontal features in semiconductor ICs, the interconnect RC delays can be quite large for some long, global interconnect wires whose length can approach the chip half perimeter. IC interconnect delays and undesirable parasitic coupling effects are the single most important factor gating improvement of chip and electronic system speed performance. While shrinking design rules boosts transistor operating speeds and increases functional density, circuit interconnect paths may dominate overall system performance by limiting the operating speed of the chip and the speed at which information is transferred to internal devices.

In order to decrease resistance and maintain conductor cross sectional area, the current art makes wire conductors tall and thin which further increases the lateral capacitance between adjacent conductors. This lateral capacitance has a reduced impact on overall speed, but results in increased “cross talk” between adjacent signal lines. Also, as the frequency of switching circuits increase to near giga hertz levels the ‘skin-effect’ of the metal conductor further increases its resistance values.

One result of continued downward feature scaling has been to increase the time required to design today's ICs. The current art for proper design of IC products has evolved into an intractable problem requiring mathematical modeling of each interconnect wire, it's parasitic interactive effects, and simulating the interaction of large number of clustered active devices and functional blocks. In the current chip design art, one of the most difficult design goals is to minimize length of each wire and minimize RC delays, especially for the long wires. This complex design process has lengthened the time it takes to bring new products to market, increasing development costs significantly.

What is needed is an improved high speed, high conductivity interconnect system to increase signal speeds, lower cross talk to adjacent conductors, and reduce power consumption.

### SUMMARY OF THE INVENTION

It is an object of the present invention to provide a method for fabricating a heat conduction device in an integrated circuit comprising the steps of (1) fabricating at least one transistor in a silicon substrate, (2) depositing a first dielectric layer on the top surface of the transistor, (3) depositing a metal catalyst layer on the surface of the first dielectric layer, (4) depositing a second dielectric layer on the surface of the metal catalyst layer, (5) etching at least one cavity through the second dielectric layer to the top surface of the metal catalyst layer, the cavity being located above the transistor. In step (6) at least one carbon nanotube is grown within the cavity, the carbon nanotube extending from the top surface of the metal catalyst layer to at least the top horizontal surface of the second dielectric layer, and in step (7) a metallic, heat conducting layer is deposited on the top surface of the second dielectric layer, such that heat generated by the transistor is conducted from the top surface of the transistor to the metallic, heat conducting layer through the carbon nanotube.

Its is another object of the present invention to provide a method for fabricating a heat conduction device in an integrated circuit die comprising the steps of (1) fabricating at least one transistor in a top surface of a silicon substrate, (2) cutting at least one cavity within the silicon substrate, the cavity extending through a back surface of the silicon substrate below the transistor, (3) depositing a catalyst layer within the cavity, and (4) growing a plurality of carbon nanotubes within the cavity, the carbon nanotubes extending from a bottom surface of the cavity to the back surface of the silicon substrate.

It is yet another object of the present invention to provide a heat conducting device within an integrated circuit structure, comprising a heat conductive network extending from a top surface of an active device layer, through a plurality of interconnect levels, to a top surface of the integrated circuit structure. The heat conductive network comprises a plurality of heat conductive vias traversing the plurality of interconnect levels. The heat conductive vias are electrically isolated from metal conductors of the interconnect levels. Heat generated by active devices in the active device layer is conducted through the heat conductive network to the top surface of the integrated circuit structure.

It is a further object of the present invention to provide an integrated circuit die having enhanced power dissipation, comprising a substrate, having a top surface upon which power generating devices of the integrated circuit die are fabricated, the substrate having a backside surface essentially parallel to the top surface. The integrated circuit die of the present invention further comprises at least one cavity, extending from the backside surface a predetermined distance toward the top surface, the predetermined distance being less than the distance between the top surface and the backside surface, and a heat conductive media contained within the cavity, the media having a thermal conductivity greater than a bulk thermal conductivity of the substrate, such that heat produced by the power generating devices is transferred to the backside surface via the heat conductive media.

### BRIEF DESCRIPTION OF THE DRAWINGS

The present invention will be better understood when consideration is given to the following detailed description thereof. Such description makes reference to the annexed drawings, wherein:

FIG. 1 is a partial cross sectional view of an integrated circuit structure having heat conducting, carbon nanotube filled vias located above a transistor junction according to an embodiment in the present invention;

FIG. 2 is a schematic top view of an integrated circuit transistor indicating a possible location of a heat conducting via according to an embodiment in the present invention;

FIG. 3 is a partial cross sectional view of an integrated circuit structure having multiple heat conducting vias extending through multiple layers of metal interconnect according to an embodiment in the present invention;

FIG. 4 is a partial cross sectional view of an integrated circuit structure having carbon nanotube filled heat conduction structures integrated into the backside of the silicon substrate according to an embodiment in the present invention;

FIG. 5 is a detailed view of ref. 404 of FIG. 4;

FIG. 6 is a partial cross sectional view of an integrated circuit structure having both heat conducting vias and backside heat conduction structures according to an embodiment in the present invention;

FIGS. 7a-e (Prior Art) are partial cross sectional views of an integrated circuit structure during the damascene process for filling a via;

FIGS. 8a-e are partial cross sectional views of an integrated circuit structure during a process for filling a carbon nanotube containing heat conduction via according to an embodiment in the present invention;

FIGS. 8f-i are partial cross sectional views of an integrated circuit structure during a streamlined process for filling a carbon nanotube containing heat conduction via according to an embodiment in the present invention;

FIG. 9 is a partial cross sectional view of an integrated circuit structure having a high speed interconnect structure mounted above a partially completed integrated circuit produced with standard technology according to an embodiment in the present invention;

FIG. 10a is a schematic top view of a high speed interconnect structure 904 of FIG. 9 according to an embodiment in the present invention;

FIG. 10b is a detailed schematic top view of ref 1002 of FIG. 10a; and

FIG. 11 is a process flow diagram for producing an integrated circuit having a high speed interconnect structure according to an embodiment in the present invention.

### DETAILED DESCRIPTION OF THE PREFERRED EMBODIMENTS

It is an object of the present invention to provide a structure in close proximity to the power generating semiconductor junctions of an integrated circuit chip specifically designed to conduct heat to the chip outer surfaces. Such a structure is compatible with current semiconductor fabrication technology, provides significantly lower thermal resistances, and is low cost.

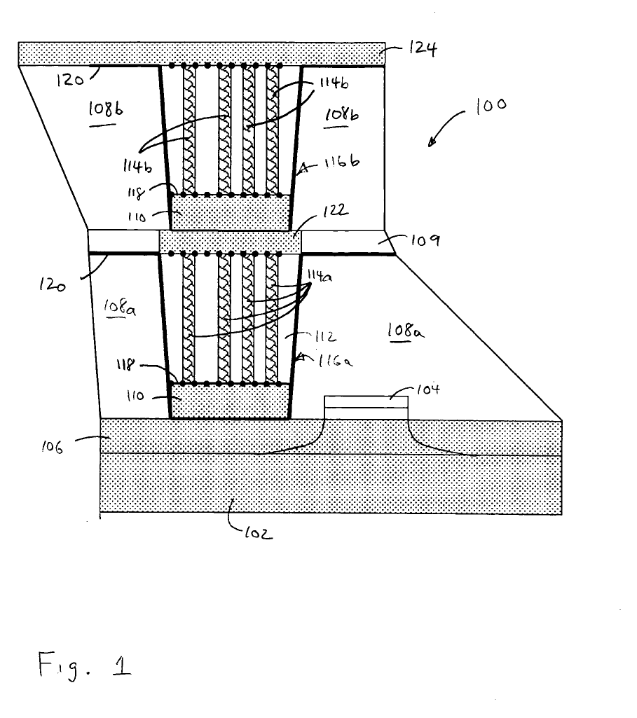

FIG. 1 is a partial cross sectional view of an integrated circuit structure 100 having heat conducting, carbon nanotube filled vias 116a,b located above a transistor junction according to an embodiment in the present invention. The silicon substrate 102 of the integrated circuit structure supports an active device layer 106 within which the junctions of the high power transistors are fabricated. Typically, a high speed integrated circuit will have a number of transistors that must dissipate relatively high power levels. These transistors will generally be functioning as clock drivers, bus line drivers, and I/O buffers and drivers. The high capacitance of the loads driven by these transistors aggravated by the very high switching frequencies, can create significant power generation, even in so called low power CMOS circuitry. Because this heat generation is localized to areas near the drain and source regions of these drive transistors, it would be of considerable benefit to remove heat from these localized hot spots if possible. FIG. 1 illustrates a subsection of a micron scale, heat conduction network designed to remove heat from localized areas on an integrated circuit die, such as power transistors or other high heat generation areas (such as laser diodes or passive components such as resistors). Heat conductive via 116a is placed directly over a power generating transistor, the gate 104 of which extends into inter metal dielectric 108a. A second heat conductive via 116b is placed in line directly above via 116a, in thermal contact with via 116a, to provide a high conductivity path through both vias. In this manner heat generated at layer 106 may be effectively transferred out of active device layer 106, where the device junctions are located. Although only two vias are illustrated, it will be obvious to those skilled in the art to see that any number of vias may be stacked to reach the top surface of the integrated circuit chip. Normally, heat is not transferred out of the chip in this direction due to the poor thermal conductivity of the multiple stacks of inter-metal dielectrics. Due to the repetitive multilayer process necessary for multiple layers of interconnect, a single via is designed to traverse one layer of metal interconnect, which includes the intermetal dielectric and metal interconnect layers. For example, via 116a extends from the top surface of the active device layer 106, through inter-metal dielectric 108a, terminating within layer 109, which would be at the same level as the first level metal interconnect for device 100. It should be noted that via 116a is electrically isolated from any metal interconnect layer, even though its top region is terminated in a metal layer 122. Metal layer 122 is primarily used to terminate the tops of any carbon nanotubes 114a (if present), and provide a low thermal conductivity transition to via 116b above. In the event that via 116b cannot be located directly above via 116a, for example, metal layer 122 may also be used to aid lateral heat conduction.

The vias 116a and 116b of FIG. 1 are shown containing carbon nanotubes 114a and 114b, respectively. Alternatively, the vias may be filled with a pure metal or metal alloy, such as copper, aluminum, tungsten, or alloys or mixtures of these metals. Carbon nanotubes are preferable even compared to a metal such as copper, since arrays of carbon nanotubes may have a thermal conductivity five times higher, exceeding 2000 Watts/m/degree Kelvin. Carbon nanotubes 114 may be present within the vias along with voids between the nanotubes. The voids may be filled with a secondary material such as copper, aluminum, tungsten or other metal. The voids may also be filled with a dielectric such as silicon dioxide, but preferably the voids are filled with a heat conductive material such as a metal or metal alloy. At the base of the via 116a is a catalyst layer 110 for nucleating the carbon nanotube growth. The catalyst layer 110 is comprised of a metal, preferably nickel or cobalt, or alloys or mixtures containing nickel or cobalt. Silicides of nickel or cobalt may also be used. Contents of the vias are isolated from the surrounding dielectric layers 108a,b and active device layer 106 by SiN barrier layer 120. Carbon nanotubes 114 are grown from top surface 118 of the catalyst layer 110 at the bottom of the via 116, to a length generally extending above metal layers 122 or 124. A number of depostion techniques are known for growing carbon nanotubes. Preferably, the carbon nanotubes are grown using plasma enhanced chemical vapor deposition (PECVD), as has been recently reported in the scientific literature and is known to those skilled in the art. Metal layers 122/124 are deposited, followed by a planarization step (usually CMP) to trim the tops of the nanotubes level with the top surface of the metalization layer 122/124. Carbon nanotubes 114 are preferably grown as uninterrupted, continuous vertical tubes from the base of the via to the top, due to the relatively small dimension between metal interconnect layers.

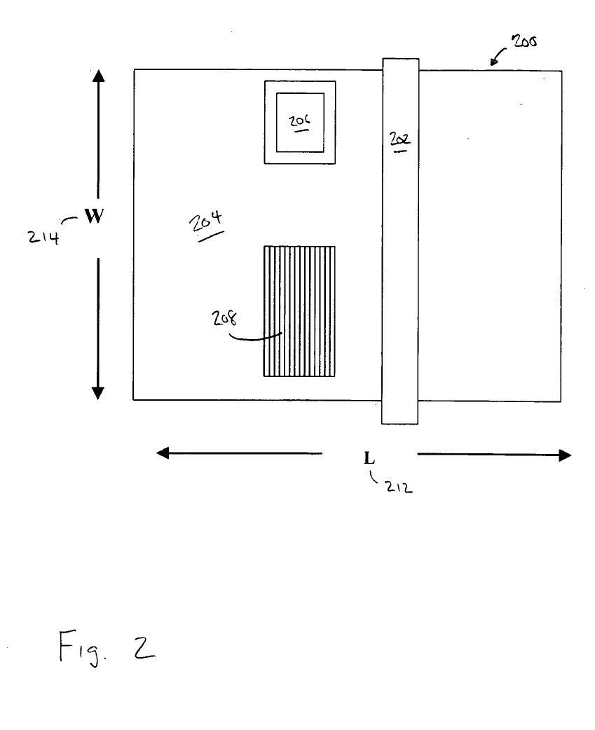

FIG. 2 is a schematic top view of an integrated circuit transistor indicating a possible location of a heat conducting via 208 according to an embodiment in the present invention. CMOS transistor 200 having a width W (214) and length L (212) is shown with gate contact 202 and source/drain area 204, and source/drain contact 206. Most of the heat generated by transistor 200 will emanate from the source/drain area 204. Placing a via 208 directly over the source/drain region of the transistor will greatly aid in removing heat where it is generated, reducing subsequent junction temperatures. The via 208 can be sized to cover as much area as practical. Although via 208 is shown above the source/drain region in this top view, it is also possible to provide a cavity or via in the substrate below the transistor 200, as will be discussed below.

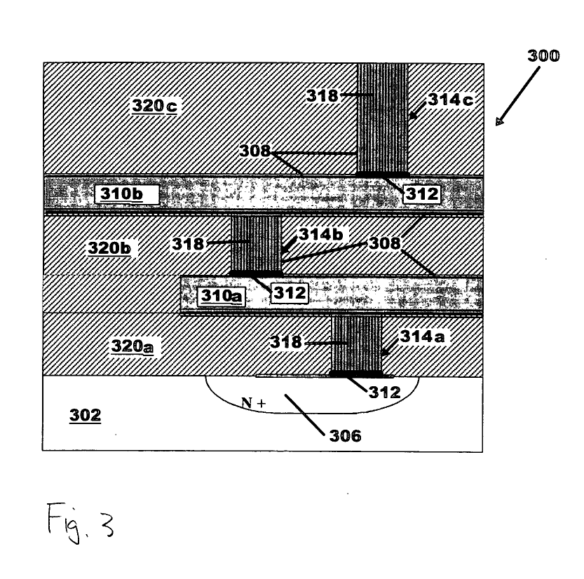

FIG. 3 is a partial cross sectional view of an integrated circuit structure 300 having multiple heat conducting vias 314 extending through multiple layers of metal interconnect according to an embodiment in the present invention. Substrate 302 contains an N doped region 306 representing a generic drain/source region of a heat generating transistor. Via 314a is placed directly over the heat generating region 306. Vias 314a-c make up a heat conducting network for transferring heat from transistor drain/source regions to the top surface of the integrated circuit die. In this example, vias 314a-c are not oriented directly above one another, but are in a staggered configuration. In this configuration, some lateral heat conduction within metal layers 310a and 310b is required to complete the heat transfer from via 314a to 314c. Although metal layers 310 are at the same vertical position as the signal interconnect levels, they are not electrically connected to them. Inter-metal dielectric layers are shown as 320a-c. In this example, vias 314a-c are filled with carbon nanotubes 318, grown from a catalyst layer 312. Alternatively, vias 314a-c may be filled with a conductive metal, as previously discussed above. Barrier layers 308 provide isolation of metal compounds contained within the vias, and may be a nitride compound, preferably silicon nitride, although titanium nitride may also be used.

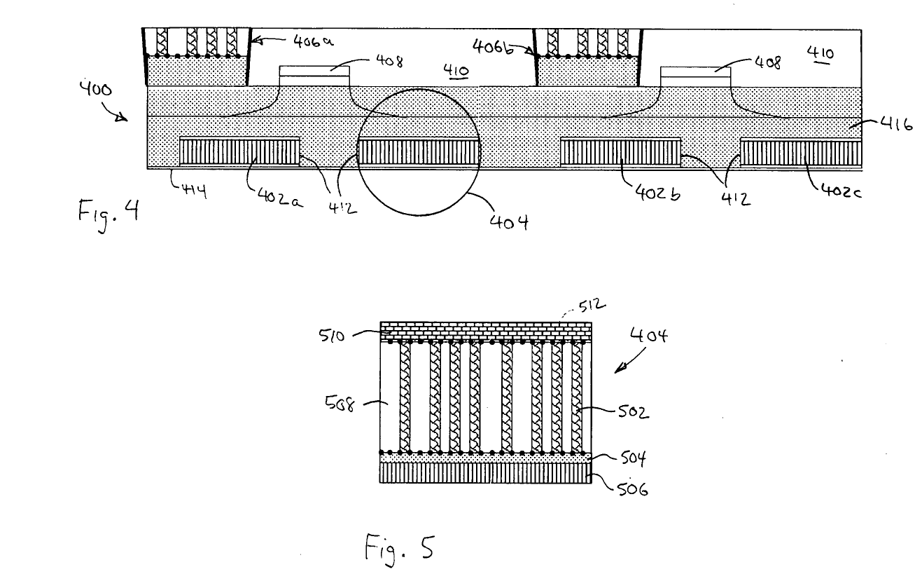

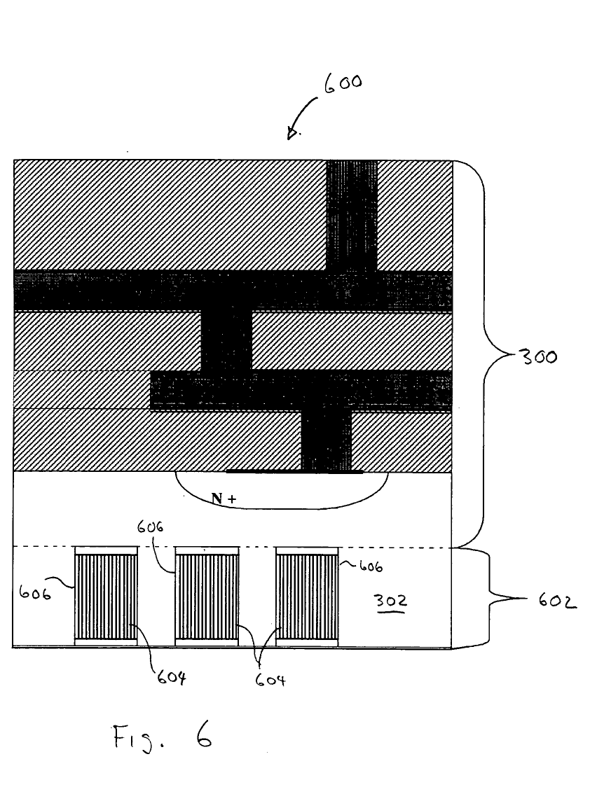

FIG. 4 is a partial cross sectional view of an integrated circuit structure 400 having carbon nanotube filled heat conduction structures 402a-c integrated into the backside of the silicon substrate according to an embodiment in the present invention. In this embodiment, heat conduction from power generating regions of the integrated circuit structure are aided by cavities or channels 412 cut into the back surface 414 of the substrate 416 to supplement heat transferred from the top side of the substrate though vias 406a,b (not to scale) extending through the first inter-metal dielectric layer 410. Structures 402a-c may be used with or without vias 406. As previously noted, cavities 412 may preferably be filled with carbon nanotubes, or with a conductive media such as metal. The cavities are preferably located below the power generating regions of the integrated circuit structure, such as the drain/source regions of CMOS transistors with gates 408. To aid in increasing heat transfer and reducing the depths of the cavities, substrate 416 may be backside ground to thin the substrate. A detailed view of a carbon nanotube filled cavity 404 is shown in FIG. 5.

FIG. 5 is a detailed view of ref. 404 of FIG. 4. Heat conducting structure 404 comprises a cavity filled with carbon nanotubes 502. The catalyst layer 510 is located at the bottom surface 512 of the cavity, the carbon nanotubes being grown from catalyst layer 510 to just beyond the back surface 414 of the substrate. Following a subsequent metal layer deposition (504, 506) on the back surface 414, the back surface may be planarized to cut off any nanotubes extending beyond the back surface, creating a flat, metallic surface layer 506 to which further heat sinking can be bonded. The interstitial voids 508 between carbon nanotubes 502 may be filled as previously discussed above.

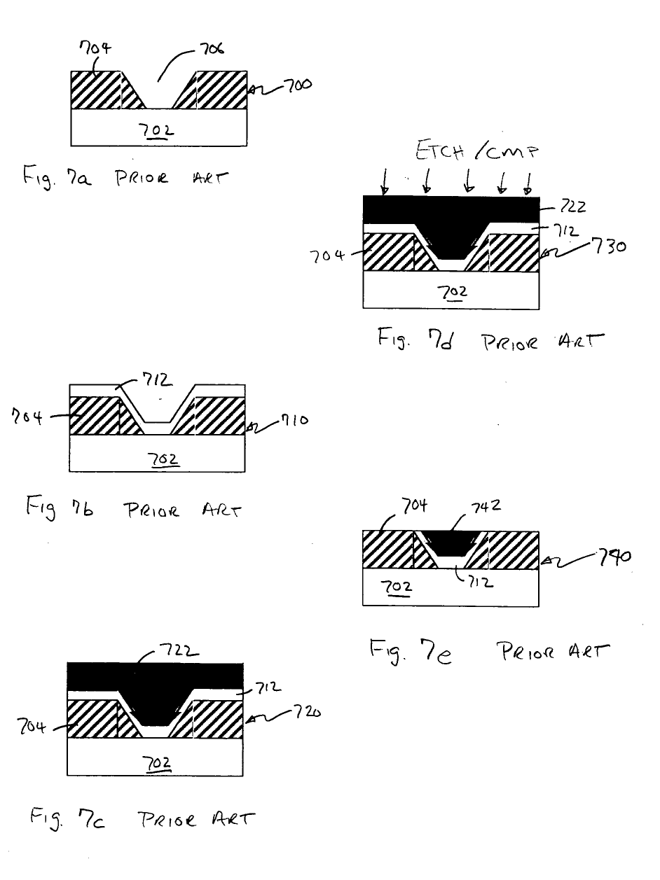

FIG. 6 is a partial cross sectional view of an integrated circuit structure 600 having both heat conducting vias and backside heat conduction structures 604 according to an embodiment in the present invention. Integrated circuit structure 600 is shown having the staggered via heat conduction network 300 of FIG. 3, coupled with backside conduction embodiment 602. Embodiment 602 comprises carbon nanotube containing heat conduction media 604 enclosed within cavities 606 cut into the backside surface of substrate 302.

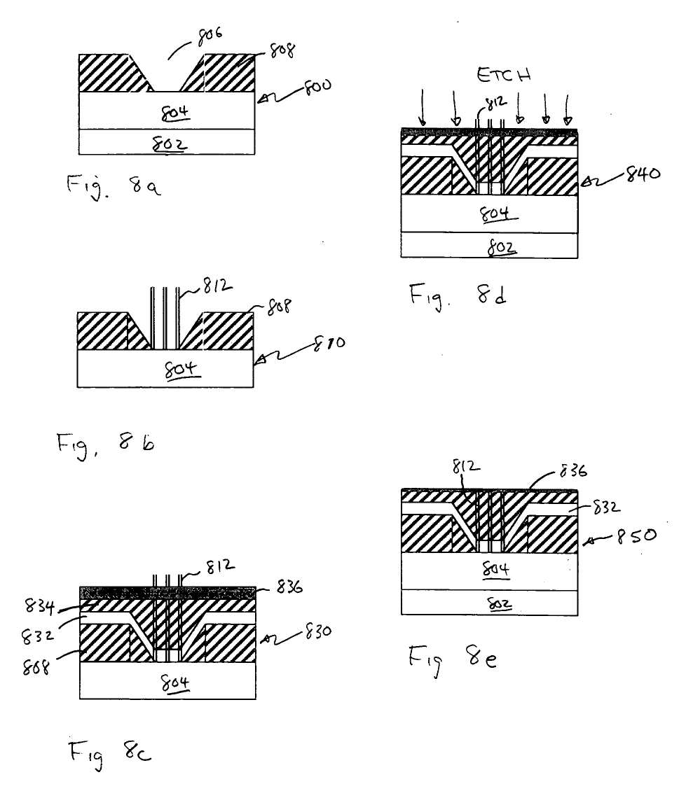

FIGS. 7a-e (Prior Art) are partial cross sectional views of an integrated circuit structure during the damascene process for filling a via. This process will be reviewed briefly for comparison to a subsequent embodiment of the present invention. In FIG. 7a, oxide layer 704 is grown over an aluminum or silicon substrate 702, then via 706 is etched within oxide 704 to expose a portion of substrate 702, leaving structure 700. In FIG. 7b, a TiN barrier layer 712 is deposited over the oxide 704 and exposed substrate 702, as in 710. In FIG. 7c, a metal layer 722 (such as tungsten) is deposited over barrier layer 712, filling the via in the process, resulting in structure 720. In FIGS. 7d and 7e, the metal layer is etched back and subsequently planarized via CMP (chemical-mechanical-planarization), removing the metal layer and barrier layer above the top surface of the oxide, but leaving the via filled with the metal 742, as in structure 740.

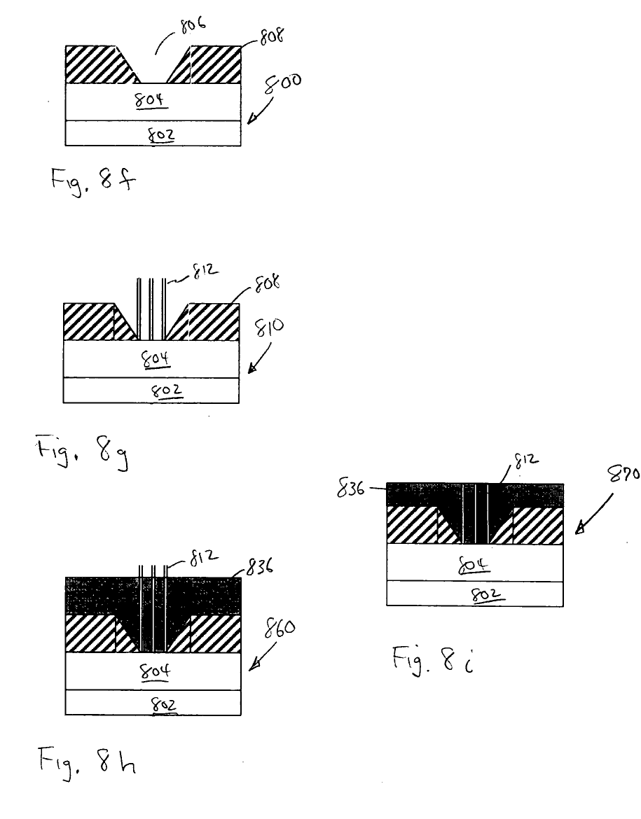

FIGS. 8a-e are partial cross sectional views of an integrated circuit structure during a process for filling a carbon nanotube containing heat conduction via according to an embodiment in the present invention. In FIG. 8a a first dielectric layer 802 is deposited over the substrate. Preferably, the first dielectric layer is silicon nitride, or less preferably, titanium nitride. A metal catalyst layer 804 is deposited on the surface of the first dielectric layer 802. Preferably the metal catalyst layer 804 is a metal compound or alloy containing nickel, cobalt, or both. Less preferably, the metal catalyst layer may contain nickel or cobalt silicides. A second dielectric layer 808 is deposited over the metal catalyst layer 804, and is preferably silicon nitride. Subsequent etching produces a cavity 806 through the second dielectric layer 808, to the top surface of the metal catalyst layer, resulting in structure 800. In FIG. 8b, carbon nanotubes 812 are selectively grown from the exposed catalyst surface at the bottom of cavity (via) 806, producing structure 810. Preferably, the carbon nanotubes are grown using plasma enhanced chemical vapor deposition (PECVD). In FIG. 8c, a third dielectric layer 832 is grown over the surface of dielectric 808. The third dielectric is preferably titanium nitride. A fourth dielectric 834 is then grown over dielectric 832, followed by a metal layer 836, finally resulting in structure 830. In FIGS. 8d and 8e, metal layer 836 is etched, then planarized with CMP, resulting in structure 850.

FIGS. 8f-i are partial cross sectional views of an integrated circuit structure during a streamlined process for filling a carbon nanotube containing heat conduction via according to an embodiment in the present invention. In FIG. 8f a first dielectric layer 802 is deposited over the substrate. Preferably, the first dielectric layer is silicon nitride, or less preferably, titanium nitride. A metal catalyst layer 804 is deposited on the surface of the first dielectric layer 802. Preferably the metal catalyst layer 804 is a metal compound or alloy containing nickel, cobalt, or both. Less preferably, the metal catalyst layer may contain nickel or cobalt silicides. A second dielectric layer 808 is deposited over the metal catalyst layer 804, and is preferably silicon nitride. Subsequent etching produces a cavity 806 through the second dielectric layer 808, to the top surface of the metal catalyst layer, resulting in structure 800. In FIG. 8g, carbon nanotubes 812 are selectively grown from the exposed catalyst surface at the bottom of cavity (via) 806, producing structure 810. Preferably, the carbon nanotubes are grown using plasma enhanced chemical vapor deposition (PECVD). The carbon nanotubes extend from the bottom of the cavity to at least the top surface of the second dielectric layer 808. In FIG. 8h, a metallic, heat conducting layer is deposited over the surface of dielectric layer 808. The metallic, heat conducting layer may be made from any metal or alloy, but preferably copper, and less preferably aluminum or tungsten. Following metal deposition, the structure 860 results. In FIG. 81, metallic, heat conducting layer 836 is planarized, producing structure 870.

It is a further object of the present invention to provide an improved high speed, high conductivity interconnect system to increase signal speeds, lower cross talk to adjacent conductors, and reduce power consumption in an integrated circuit.

In one embodiment, a ‘flip-chip’ type of structure is proposed containing nanowires (carbon or silicon). The high speed interconnect (flip-chip) structure is “piggy-backed” on to a chip constructed with standard fabrication techniques, but with fewer interconnect levels. The new structure accommodates some of the chip's difficult or bottleneck wiring tasks (i.e., long wires, power feeding wires as well as other components such as passive components). The lower level, short range interconnect wiring is left on the primary integrated circuit. The primary integrated circuit is modified with additional interconnect vias that couple to the flip-chip structure, which is mounted on top of the primary IC.

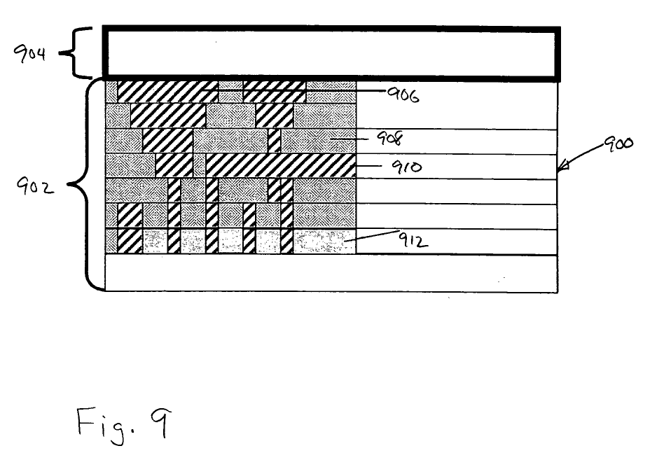

FIG. 9 is a partial cross sectional view of an integrated circuit structure 900 having a high speed interconnect structure 904 mounted above a partially completed integrated circuit 902 produced with standard technology according to an embodiment in the present invention. The high speed interconnect flip-chip 904 is mounted above the integrated circuit 902, and effectively replaces a number of metal interconnect layers in the standard chip. In the flip-chip structure 904, nanowires of dimensions between 1-100 nanometers are created via self-assembly and deposited on a suitable substrate according to the current methods of creating silicon or carbon nanowires. These nanowires have capacitances per unit length many orders of magnitude smaller than micro-wires and interconnect wiring in a standard IC. Depending on their total resistance, the wire RC delays will enable much better speed performance of silicon chips. The nanowire arrays are grown on top of an appropriate substrate using catalyst materials such as Si, Cu, Co, and Ni. Preferably, the nanowire arrays are made with carbon nanotubes or silicon nanowires. The substrate material may be silicon, alumina, SiO₂, or quartz. Connection between the flip-chip 904 and IC 902 is made by vias 906. Pre-metal dielectric 912, first metal interconnect layer 910 and inter-metal dielectric layer 908 are part of the standard integrated circuit fabrication structure. Alternatively, flip chip 904 can sit as an independent chip mounted on contact openings of the passivation layer of standard semiconductor chip.

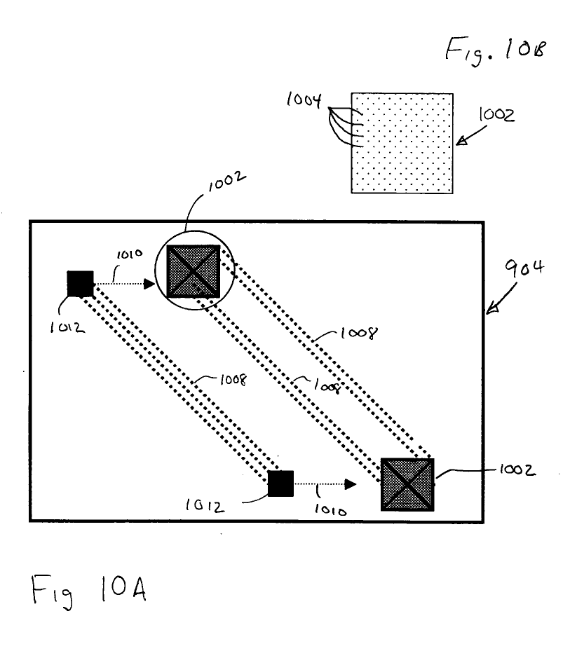

FIG. 10a is a schematic top view of a high speed interconnect structure 904 of FIG. 9 according to an embodiment in the present invention. An initial pattern of nanowires 1008 (carbon nanotubes or silicon) is created so that one or more parallel nanowires start and end at locations with contact electrodes 1002, 1012 of appropriate dimensions. These contact electrodes will be connected to the via-contacts (1004 in FIG. 10b) of the desired interconnects of the underlying main chip. For each application and main chip die, the location and shape of the metal electrodes on the flip-chip should be placed and aligned with the connecting vias of the actual silicon chip underneath. The x-y coordinates of the vias are provided by the main chip layout which would otherwise use long metal wires of the conventional art to connect signals of interest. Wires that are deemed ‘too long’ or, for whatever reason ‘too unreliable’ by the chip design and layout software are replaced by nano wires (carbon nanotubes or silicon) on the flip-chip. This is accomplished by chip design and analysis software and by connecting ‘via-holes’ brought to the appropriate x-y locations. Sets of long nanowires 1008 are tested in situ (at wafer level) for RC delays within a minimum tolerance value necessary for appropriate switching levels. An appropriate set of nano-wires, which meet maximum RC delay specifications, are selected. Non-functional nanowires or nanowires outside of RC delay specs are cut out using, for example laser or electron beam (E-Beam) trimming. A separate test circuit may be placed in the flip-chip. The test structure uses multiplexing circuitry to minimize the number of large I/O contacts required to connect to test equipment. Spectroscopy (particularly Raman) measurements may be used to ascertain parameter characteristics of nanowires. Following the spectroscopy measurements, nanowires with undesirable characteristics may be trimmed out. Further connections can be made to desired nanowires by patterning with additional, conventional metal lines if necessary. E-beam lithography may be used to customize each individual die metal pattern 1010 to complement and connect the generic topology of nanowires of each die on the wafer. E-Beam lithography is cost effective since it will handle the relatively small number of wires replaced by nanowires. In order to create non-crossing topology of nanowires, a single layer router is needed to sort the order of via-holes which need to be connected. In FIG. 10a, a diagonal, non-manhattan routing scheme is used to connect the vias with nanowires. If the number of long nanowires is large, the single layer approach might not be sufficient and a 2-layer topology of nanowires will be required as a routing scheme.

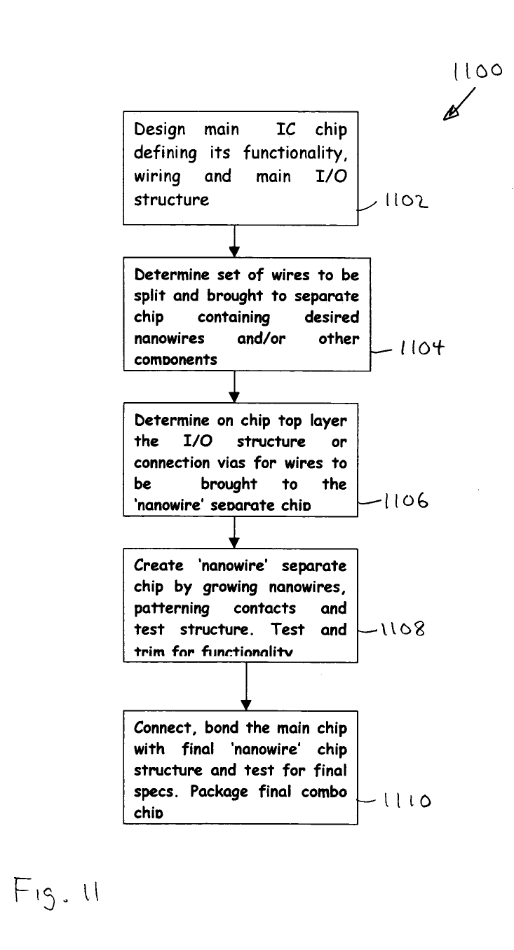

FIG. 11 is a process flow diagram 1100 for producing an integrated circuit having a high speed interconnect structure according to an embodiment in the present invention. In step 1102, the main integrated circuit chip is designed, defining its functionality, wiring, and main I/O structure. In step 1104, wiring and components to be added to the flip-chip are determined. In step 1106, the flip-chip I/O structure and via positions are determined. In step 1108, the flip-chip structure is fabricated and tested. The following process steps are utilized:

1) Synthesize, grow or deposit a fixed array topology with a large number of nanowires on the surface of an appropriate substrate. If carbon nanotubes are used, only multi-wall carbon nanotubes with larger diameters are grown to obtain metal only type of nanowires.

2) Enlarge or deposit metal electrodes at the extremities of the nanowires or circuit structures to allow for wafer level probe testing. In the case of carbon nanotubes, Raman spectroscopy is used for non-contact probing.

3) Use E-beam or laser trimming to cut out non-working or out-of-specs nanowires.

4) Use E-beam lithography to create a unique ‘mask’ pattern resist for metal deposition necessary to create functional wiring chips. This extra metal deposition is required to connect nanowire structure to ‘vias’ connecting to the conventional chip lying underneath.

5) Deposit the extra metal across the wafer of the separate chip structure, seal it.

6) Saw or slice each die

In step 1110, the flip-chip is bonded to the main IC chip, and the combination is tested and then packaged.

What is claimed is:

1. A method for fabricating a heat conduction device in an integrated circuit comprising the steps of:
(1) fabricating at least one transistor in a silicon substrate;
(2) depositing a first dielectric layer on a top surface of said at least one transistor;
(3) depositing a metal catalyst layer on a top surface of said first dielectric layer;
(4) depositing a second dielectric layer on a top surface of said metal catalyst layer;
(5) etching at least one cavity through said second dielectric layer to the top surface of said metal catalyst layer, said at least one cavity being located above said at least one transistor;
(6) growing at least one carbon nanotube within said at least one cavity, said at least one carbon nanotube extending from the top surface of said metal catalyst layer to at least a top surface of said second dielectric layer; and,
(7) depositing a metallic, heat conducting layer on the top surface of said second dielectric layer, such that heat generated by said transistor is conducted from the top surface of said transistor to said metallic, heat conducting layer through said at least one carbon nanotube.

2. A method for fabricating a heat conduction device in an integrated circuit as recited in claim 1 wherein the first and second dielectric layers comprise silicon nitride.

3. A method for fabricating a heat conduction device in an integrated circuit as recited in claim 1 wherein said metal catalyst layer comprises nickel.

4. A method for fabricating a heat conduction device in an integrated circuit as recited in claim 1 wherein said metal catalyst layer comprises cobalt.

5. A method for fabricating a heat conduction device in an integrated circuit as recited in claim 1 wherein said metallic, heat conducting layer comprises copper.

6. A method for fabricating a heat conduction device in an integrated circuit as recited in claim 1 wherein said metallic, heat conducting layer comprises aluminum.

7. A method for fabricating a heat conduction device in an integrated circuit as recited in claim 1 wherein said metallic, heat conducting layer is deposited within said at least one cavity in contact with said at least one carbon nanotube.

8. A method for fabricating a heat conduction device in an integrated circuit as recited in claim 1 wherein a top surface of said metallic, heat conducting layer is planarized following deposition, such that said at least on carbon nanotube does not extend above said top surface of said metallic, heat conducting layer.

9. A method for fabricating a heat conduction device in an integrated circuit as recited in claim 1 wherein said at least one cavity is located above a drain of said at least one transistor.

10. A method for fabricating a heat conduction device in an integrated circuit as recited in claim 1 wherein said at least one cavity is located above a source of said at least one transistor.

11. A method for fabricating a heat conduction device in an integrated circuit as recited in claim 1 wherein said at least one cavity is located above a heat generation area of said at least one transistor.

12. A method for fabricating a heat conduction device in an integrated circuit die comprising the steps of:
(1) fabricating at least one transistor in a top surface of a silicon substrate;
(2) cutting at least one cavity within said silicon substrate, said at least one cavity extending through a back surface of said silicon substrate below said at least one transistor;
(3) depositing a catalyst layer within said at least one cavity; and,
(4) growing a plurality of carbon nanotubes within said at least one cavity, said plurality of carbon nanotubes extending from a bottom surface of said at least one cavity to the back surface of the silicon substrate.

13. A method for fabricating a heat conduction device in an integrated circuit die as recited in claim 12, further comprising the step of:
(5) depositing a metallic, heat conducting layer on the back surface of said silicon substrate and within said at least one cavity, subsequent to the growth of said plurality of carbon nanotubes, said metallic, heat conducting layer in contact with said plurality of carbon nanotubes.

14. A method for fabricating a heat conduction device in an integrated circuit die as recited in claim 13, further comprising the step of:
(6) planarizing the back surface of said silicon substrate, such that said plurality of carbon nanotubes does not extend through said metallic, heat conducting layer.

15. A method for fabricating a heat conduction device in an integrated circuit die as recited in claim 13 wherein said metallic, heat conducting layer comprises copper.

16. A method for fabricating a heat conduction device in an integrated circuit die as recited in claim 13 wherein said metallic, heat conducting layer comprises aluminum.

17. A method for fabricating a heat conduction device in an integrated circuit die as recited in claim 12 wherein said catalyst layer comprises nickel.

18. A method for fabricating a heat conduction device in an integrated circuit die as recited in claim 12 wherein said catalyst layer comprises cobalt.

19. A method for fabricating a heat conduction device in an integrated circuit die as recited in claim 12 wherein said at least one cavity is located below a drain of said at least one transistor.

20. A method for fabricating a heat conduction device in an integrated circuit die as recited in claim 12 wherein said at least one cavity is located below a source of said at least one transistor.

21. A method for fabricating a heat conduction device in an integrated circuit die as recited in claim 12 wherein said at least one cavity is located below a heat generation area of said at least one transistor.

22. A heat conducting device within an integrated circuit structure, comprising
a heat conductive network extending from a top surface of an active device layer, through a plurality of interconnect levels, to a top surface of the integrated circuit structure,
said heat conductive network comprising a plurality of heat conductive vias traversing said plurality of interconnect levels,
said heat conductive vias being electrically isolated from metal conductors of said plurality of said interconnect levels,
such that heat generated by active devices in said active device layer is conducted through said heat conductive network to the top surface of the integrated circuit structure.

23. A heat conducting device within an integrated circuit structure as recited in claim 22, wherein said plurality of heat conductive vias comprise carbon nanotubes.

24. A heat conducting device within an integrated circuit structure as recited in claim 22, wherein said plurality of heat conductive vias comprise a material selected from the group consisting of copper, aluminum, polysilicon, and tungsten.

25. A heat conducting device within an integrated circuit structure as recited in claim 22, wherein said plurality of heat conductive vias are oriented in a direct line from said top surface of the active device layer to said top surface of the integrated circuit structure.

26. A heat conducting device within an integrated circuit structure as recited in claim 22, wherein each via in said plurality of heat conductive vias traverses a single level of interconnect, said single level of interconnect comprising a single layer of interconnect metal over a single layer of intermetal dielectric.

27. An integrated circuit die having enhanced power dissipation, comprising:
a substrate, having a top surface upon which power generating devices of said integrated circuit die are fabricated, said substrate having a backside surface essentially parallel to said top surface;
at least one cavity, extending from said backside surface a predetermined distance toward said top surface, said predetermined distance being less than the distance between said top surface and said backside surface; and
a heat conductive media contained within said at least one cavity, said media having a thermal conductivity greater than a bulk thermal conductivity of said substrate, such that heat produced by said power generating devices is transferred to the backside surface via said heat conductive media.

28. An integrated circuit die having enhanced power dissipation as recited in claim 27, wherein said heat conducting media comprises copper.

29. An integrated circuit die having enhanced power dissipation as recited in claim 27, wherein said heat conducting media comprises carbon nanotubes.

30. An integrated circuit die having enhanced power dissipation as recited in claim 27, wherein said at least one cavity is located directly below at least one power generating device in said substrate.

31. An integrated circuit die having enhanced power dissipation as recited in claim 30, wherein said at least one power generating device is a transistor having a drain, said at least one cavity being located directly below said drain.

32. An integrated circuit die having enhanced power dissipation as recited in claim 30, wherein said at least one power generating device is a transistor having a source, said at least one cavity being located directly below said source.
